(19) United States
(12) Patent Application Publication
(10) Pub. No.: US 2009/0302479 A1
(43) Pub. Date: Dec. 10, 2009

(54) SEMICONDUCTOR STRUCTURES HAVING VIAS

(75) Inventor: Timothy J. Whetten, Fort Collins, CO (US)

Correspondence Address: Kathy Manke;Avago Technologies Limited, 4380 Ziegler Road, Fort Collins, CO, 80525, US

(73) Assignee: Avago Technologies Wireless IP (Singapore) Pte. Ltd., Singapore (SG)

(21) Appl. No.: 12/135,014

(22) Filed: Jun. 6, 2008

(51) Int. Cl. H01L 23/52; H01L 21/311

(52) U.S. Cl. 257/774; 438/694; 257/E23.141; 257/E21.249

(57) ABSTRACT

A semiconductor structure comprises a substrate having a front surface and a back surface and a via extending from the first surface, the via comprising. The via comprises: a first side; a second side parallel to the first side; a first end extending between the first side and the second side; a second end opposite to the first end and extending between the first side and the second side. The first and second ends form oblique angles with the first and second sides. A method of fabricating the vias is also described.

### BACKGROUND

As semiconductor packing densities continue to increase, demands are placed on feature sizes and pitch, or spacing between adjacent features of the semiconductor. One component often fabricated in semiconductor wafer processing is a via. Vias are often provided from through a wafer or substrate, and are filled or otherwise provided with a conductive material, such as a metal/metal alloy. Vias are used to provide electrical connections from one surface of the semiconductor substrate to the opposing surface, and from one substrate to another.

As the need for more densely packed electrical connections has increased, so too have the packing densities of vias on substrates. Increased densities has resulted in decreased areal dimensions of the vias, while the depth of the via has remained comparatively unchanged. This results in a comparatively high aspect ratio, and difficulties in fabricating vias.

One problem that occurs in known via fabrication is defect generation in known vias having substantially right-angle corners. FIG. 1A is a top view of a known semiconductor wafer 101 having a plurality of vias 102 extending from a top surface through the wafer 101. The vias are designed to be substantially rectangular in areal dimension. However, in order to create a through-via, plasma etching is often used with a photoresist layer (not shown) forming a mask for the etching sequence. At the right-angle corners, defects 104 can be created during the plasma etchings sequence. As shown more clearly in FIG. 1B, the defect forms somewhat of a crater outside the desired shape and areal dimension of the via 102. These defects are a result of resist pull-back from the straight edges at substantially right-angles. The defect 104 does not extend through the thickness of the wafer normally, but does present problems in subsequent processing (e.g., metallization or plating).

As is known, after the via 102 is formed, metal or other conductors are patterned over the via and form a contact pad. The pad is normally slightly larger in areal dimension than the opening of the via 102. For example, the metal pad 105 (also referred to as the top metal) is disposed over the via, and is slightly larger than the ideal areal dimension (i.e., rectangular area) of the via 102. While the pad 105 extends beyond the ideal areal dimension, the pad 105 does not encompass the defect 104. As should be appreciated, in order for the pad 105 to be reliable, it must cover the defect 104 in addition to the via 102. Therefore, the in an effort to ensure reliability, the area of the pad 105 must be made larger and, understandably, results in a reduction of the packing density of the vias 102.

In an effort to reduce the likelihood of the formation of defects such as defect 104 during etching, ‘rounded’ photoresist patterns have been used. However, as smaller feature sizes are desired, it has been found that comparatively smaller round resist masks are not conducive to deep etching. To this end, as is known, for certain common plasma etch sequences, the etch rate decreases exponentially with aspect ratio. As a result, the etching effectively ceases when the aspect ratio is too great. For example, circular mask openings having diameters on the order of 30 μm have insufficient areal dimensions for the plasma process to etch through the thickness of the wafer.

While larger circular openings may foster through-wafer via etching, packing densities are increased beyond acceptable limits in certain design layouts. Thus, defects can be reduced by using circular openings, but can result in unacceptable via etching, or unacceptable packing densities.

There is a need, therefore, for a method of fabricating vias and vias that overcomes at least the shortcoming of methods and resulting vias discussed above.

### SUMMARY

In accordance with a representative embodiment, a semiconductor structure includes a substrate having a front surface and a back surface and a via extending from the first surface. The via comprises: a first side; a second side parallel to the first side; a first end extending between the first side and the second side; a second end opposite to the first end and extending between the first side and the second side. The first and second ends form oblique angles with the first and second sides.

In another representative embodiment, a method of forming a via in a substrate comprises: patterning a layer of photoresist over the substrate to form an opening in the photoresist, wherein the opening comprises: a first side; a second side parallel to the first side; a first end extending between the first side and the second side; a second end opposite to the first end and extending between the first side and the second side, wherein the first and second ends form oblique angles with the first and second sides. The method also comprises etching through the substrate to form the via.

In accordance with another representative embodiment, a semiconductor structure comprises a substrate having a front surface and a back surface; and an elliptical via extending from the front surface through to the back surface. The elliptical via has an two foci that do not coincide.

In accordance with another representative embodiment, a method of forming a via in a substrate comprises: patterning a layer of photoresist over the substrate to form an elliptical opening in the photoresist; and etching through the substrate to form the via.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1A is a top view of a prior art semiconductor wafer showing vias and defects.

FIG. 1B is an enlarged view of via and having a defect shown in FIG. 1A.

FIG. 2A is a top view of a semiconductor wafer showing vias in accordance with a representative embodiment.

FIG. 2B is a partial cross-sectional view of two adjacent vias shown of FIG. 2A.

FIG. 3 is a top view of a semiconductor wafer showing vias in accordance with a representative embodiment.

FIG. 4 is a top view of a semiconductor wafer showing vias in accordance with a representative embodiment.

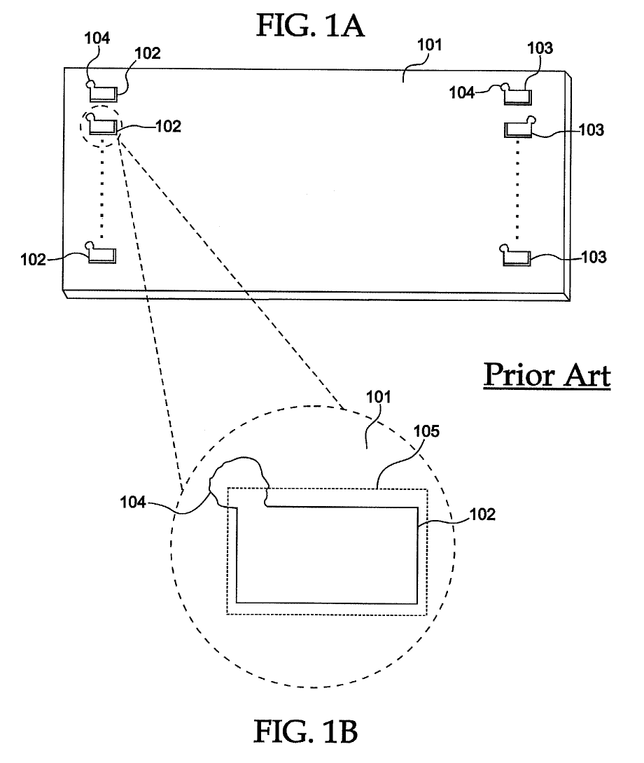

### DEFINED TERMINOLOGY

As used herein, the terms ‘a’ or ‘an’, as used herein are defined as one or more than one.

As used herein, the terms semi-ellipse and semi-elliptical mean a portion of an ellipse, up to and including a half of the ellipse. The semi-ellipse includes certain properties of the ellipse, such as the eccentricity.

As used herein, and in addition to their ordinary and customary meanings, terms of degree such as ‘approximately’ and ‘substantially’ mean to within acceptable tolerances.

### DETAILED DESCRIPTION

In the following detailed description, for purposes of explanation and not limitation, representative embodiments disclosing specific details are set forth in order to provide a thorough understanding of the present teachings. Descriptions of known devices, materials and manufacturing methods may be omitted so as to avoid obscuring the description of the example embodiments. Nonetheless, such devices, materials and methods that are within the purview of one of ordinary skill in the art may be used in accordance with the representative embodiments.

Representative embodiments are described in the context of III-V semiconductors, such as GaₓAs₁₋ₓ and other III-V compounds. However, the methods and structures are contemplated for use more broadly in other materials, such as Si, SiGe, SiC and semiconductor on insulator (SOI). Furthermore, the methods and structures are also contemplated for use in micro-electromechanical (MEMs) devices and systems. As is known, MEMs devices and systems may be fabricated from semiconductor wafers and other materials such as plastics and other polymers.

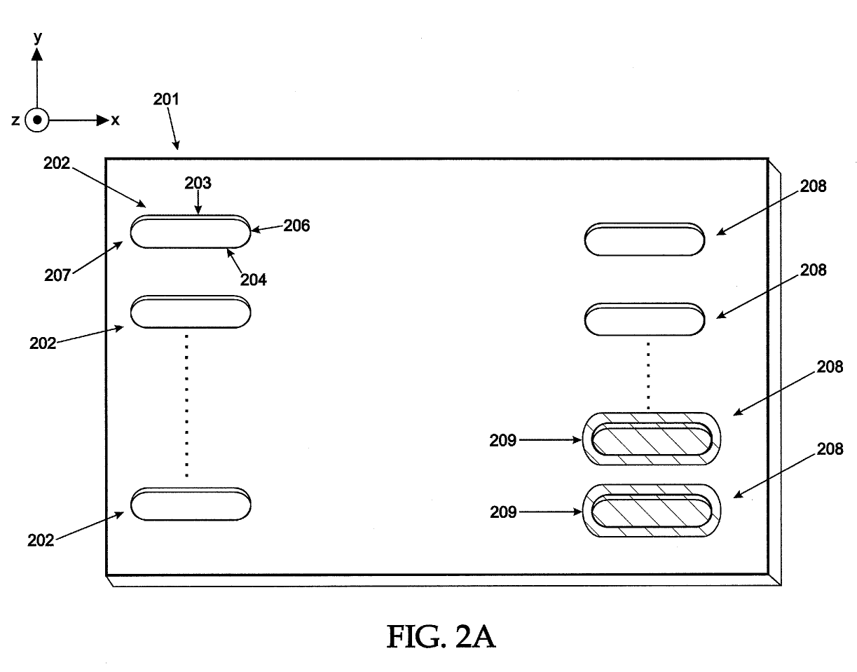

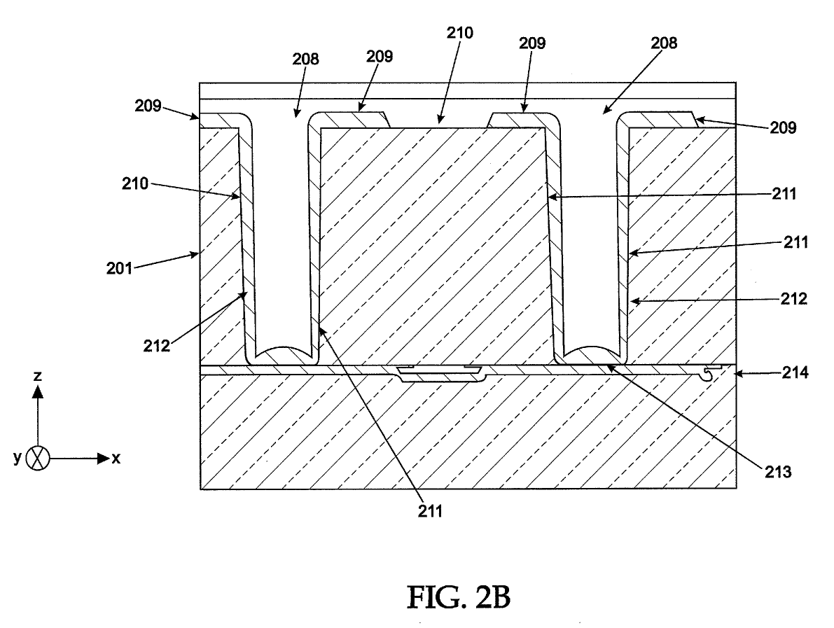

FIG. 2A is a top view of a semiconductor wafer (substrate) 201 showing vias 202, 208 disposed therein according to a representative embodiment. The vias 202, 208 are substantially identical, with vias 202 being on one portion of the wafer 201, and vias 208 being disposed on another portion of the wafer 201. As will be appreciated, in many applications, packing density in one lateral dimension (e.g., the y-direction in the coordinate axis shown) is a significant consideration in design layout of an integrated circuit or other component formed from the wafer 201. As such, the y-dimension of the vias 202, 208 are small in comparison to the x-direction of the vias 202, 208. As should be appreciated, dimension of the vias in one lateral dimension (the x-dimension in the illustrative embodiment) may be greater than in the other lateral the y-dimension thereby ensuring the suitable etch rates through the wafer 201; yet the packing density in the more precious lateral y-dimension is realized at a suitable level.

In a representative embodiment, the vias 202, 208 each comprise a first side 203 and a second side 204, which are substantially parallel. A first end 206 end extends between the first side 203 and the second side 204; and a second end 207 extends between the first side 203 and the second side 204 and is opposite to the first end 206. In a representative embodiment, the first end 206 and the second end 207 are semi-elliptical in shape, and provide the ‘rounded’ edges required to substantially avoid defects from forming due to photoresist pullback during plasma etching. In other representative embodiments, the semi-ellipses of the first and second ends 206, 207 have an eccentricity of 1.0; and thus are semi-circular in shape.

The vias 202, 208 are fabricated using a photoresist (not shown) as a mask disposed over the wafer 201. The photoresist (resist) is patterned with openings having the outlines of the vias 202, 208 using known processing methods. Next, an etching sequence is carried out to etch the vias 202, 208 through the wafer 201. Illustratively, the etching is a high rate plasma etching sequence such as an inductively coupled plasma etching process. In a representative embodiment, the inductively coupled plasma etch comprises BCl₃ and Cl₂, although other etchants may be used. After etching, the resist is removed leaving the non-conductive via. In applications where the vias 202, 208 are used to provide electrical connections or heat sinks, or both, the vias 202, 208 are metallized by known methods. For instance, a metal/metal alloy may be sputter deposited by known methods, followed by a wet plating sequence. The sputter deposition may comprise Ti/W and the wet plating comprises Au. The resultant metal pads 209 are shown over two adjacent the vias 208 to illustrate the comparatively tight packing density of the vias 208.

The maximum space between the vias tends to be approximately the same as the smallest dimension of the via. Thus the maximum packing density for a via having lateral dimensions of approximately 30 μm by approximately 60 μm would be approximately 60 μm in the y direction and approximately 90 μm in the x direction. In the representative embodiment the maximum packing density is 60 μm in the y direction and 90 μm in the x direction. Of course, the direction of maximum packing density might be ‘rotated’ in different areas of the chip depending on the layout requirements.

As discussed above, the first and second ends 206, 207 may be semi-elliptical in shape; and thus are based on an ellipse having a specific eccentricity. As should be appreciated, the eccentricity of an ellipse that is not a circle is greater than zero and less than one; and the special case of an ellipse with eccentricity 1 is a circle. The eccentricity is selected so that the semi-ellipse spans the distance from the first side 203 to the second side 204; and this is one of the lateral dimensions of the via 202. This lateral dimension of the vias establishes the packing density and the pitch of adjacent vias 202, 208, with space left to ensure isolation of contact pads 209. As alluded to previously, the lateral dimension along the x-direction in the coordinate system of FIG. 2 of the vias can be made comparatively small (e.g., on the order of approximately 30 μm), yet allowing the etching process to etch through the wafer 201 or other substrate because of the lateral dimension along the y-direction in the coordinate system of FIG. 2 accorded the via.

In representative embodiments, lateral (x) dimension of the vias 202, 208 (i.e., length of the first and second sides 203, 204) are approximately 50 μm to 60 μm; the lateral (y) dimension of the vias (i.e., the separation of the sides 203, 204) are approximately 30 μm; and the aspect ratio of the vias 202, 208 are approximately 3:1 and may be approximately 5:1. Aspect ratio is typically used to describe the ratio of minimum lateral dimension (x or y) to the vertical (z dimension in the coordinate system shown) through the wafer. In the representative embodiment, the dimension z is 100 μm, so the aspect ratio is 3.3. In the representative embodiment the vertical (z direction) walls of the via are substantially perpendicular to the opposing surfaces of the wafer 201 (i.e., substantially perpendicular to the x-y plane), although they may be sloped.

FIG. 2B is a partial cross-sectional view illustrating of two adjacent vias 208, which has been metallized. The vias 208 include a pad 209 disposed over a surface 210 of the wafer 201 and circumscribes the via opening at the surface 210. Along its interior walls 211 the via 208 is substantially plated with electrically conductive material 212 such as metal or metal alloy by methods known to one having ordinary skill in the art, such as described above. Alternatively, the via 208 may be filled (e.g., a damascene structure) with a suitable conductive material (e.g., Ti/W or W). In either case, the via 208 includes a lower conductive surface 213, which makes electrical contact to contacts on another substrate 214.

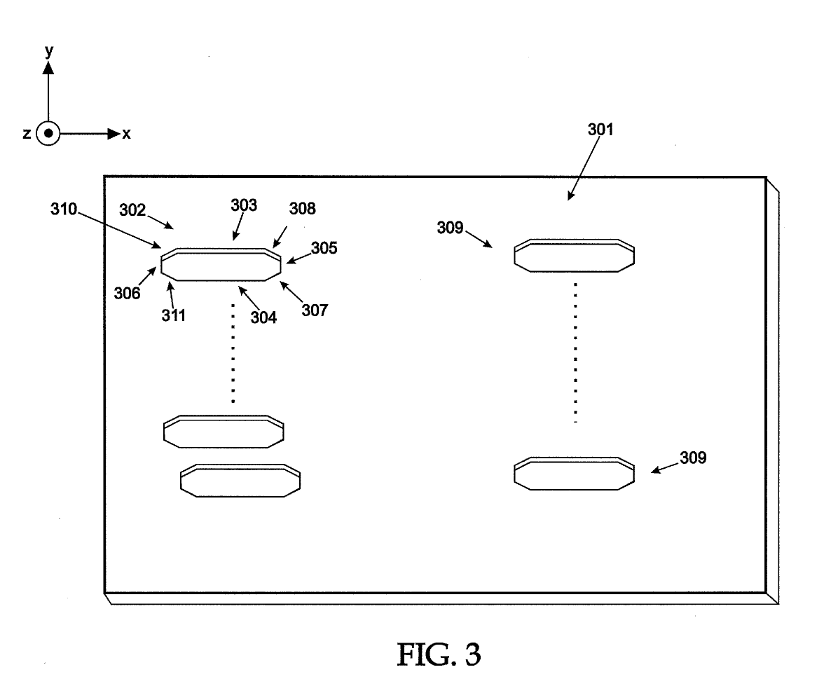

FIG. 3 is a top view of a semiconductor wafer (substrate) 301 showing vias 302, 309 disposed therein according to a representative embodiment. The substrate 301 and vias 302, 309 share many common features with and are fabricated using similar or identical methods to those described in conjunction with the embodiments of FIG. 2. These features and methods are not repeated so as to avoid obscuring the description of the presently described embodiments.

The vias 302, 309 are substantially identical and each comprise a first side 303, a second side 304, a first end 305 and a second end 306. The first end 305 comprises a first edge 307 and a second edge 308; and the second end 306 comprises a third edge 310 and a fourth edge 311. The edges 307, 308 are oriented at an oblique angle to the second and first sides, respectively; and the edges 310, 311 are oriented at an oblique angle with the first and second sides, respectively. In the representative embodiment shown in FIG. 3, the lengths and angles of orientation of the edges 307, 308 are substantially the same; and the lengths and angles of orientation of the edges 310, 311 are substantially the same. Moreover, the edges 307, 308 are substantially the same length and angular orientation as the edges 310, 311. As will be appreciated, the selected lengths and angular orientations of the edges 307,308, 310, 311 are not essentially the same; nor are the lengths and angles of orientation of the two edges of a particular end 305, 306.

Like the ‘rounded’ ends 206, 207 of the representative embodiments of FIG. 2, Applicants have discovered that having edges 307, 308, 310, 311 disposed at oblique angles relative to respective first and second sides 303, 304 of the vias 302, 310 reduces, if not eliminates the defects due to resist pullback during plasma etching. To this end, the photoresist (not shown) is deposited and patterned in the shape of the vias 302, 311. The plasma etching sequence is effected and the vias are formed through the wafer 301. After the resist is removed, the vias are metallized by known methods such as described above.

Also, like the vias having rounded ends 206, 207 of the representative embodiments of FIG. 2, the lateral (y) dimension of the vias are small compared to the lateral (x) dimensions. Thus, the vias can be comparatively densely packed in the y-direction, even after metallization. In representative embodiments, the vias 302, 310 have dimensions substantially the same as those of the embodiments of FIG. 2; and have an aspect ratio also substantially the same as those of the embodiments of FIG. 2.

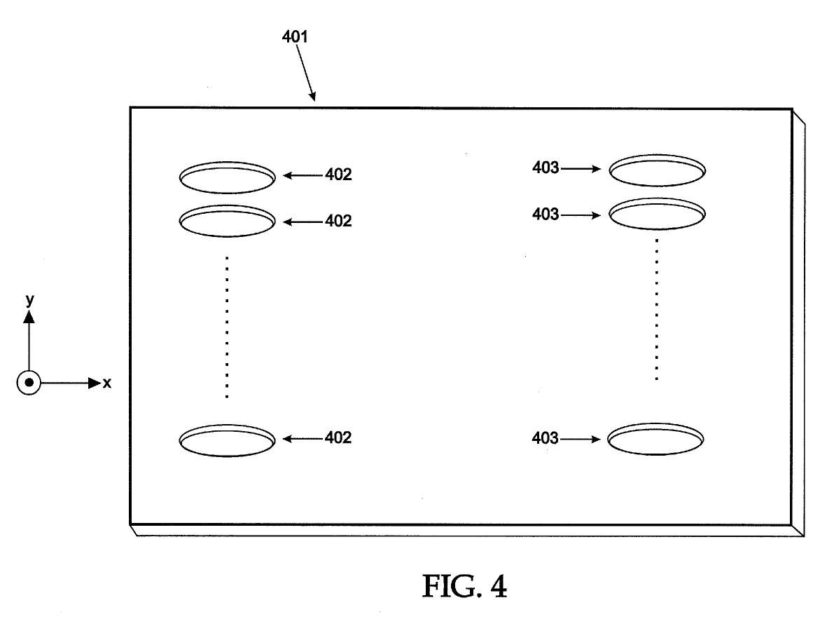

FIG. 4 is a top-view of a semiconductor wafer (substrate) 401 showing vias 402, 403 disposed therein according to a representative embodiment. The substrate 401 and vias 402, 403 share many common features with and are fabricated using similar or identical methods to those described in conjunction with the embodiments of FIGS. 2 and 3. These features and methods are not repeated so as to avoid obscuring the description of the presently described embodiments.

The vias 402, 403 of the representative embodiments are elliptical in shape. The ellipses have the requisite ‘rounded’ edges and as such, enable fabrication substantially without defects resulting from photoresist pullback described above. Moreover, the eccentricities of the vias are selected so that their respective minor axes (b) are small compared to their respective major axes (a). In particular, the length of the minor axis (oriented along the y-direction) of vias 402, 403 is small compared to the length of the major axis (along the x-direction) so that the packing density in the direction of the minor axes can be comparatively large. In addition, because the major axis is comparatively large, the areal dimensions of the ellipses are large enough to allow etching through the wafer thickness to be completed. Stated somewhat differently, the length of the major axis is selected to ensure that the areal dimensions of the elliptical openings in the photoresist are great enough to accord an aspect ratio that is low enough for a suitable plasma etch rate to be attained. Thereby, etching through the thickness of the wafer 401 from a front surface to a rear (opposing) surface to be realized.

In a representative embodiment, the photoresist layer (not shown) is provided over the substrate 401 and patterned to form an etch mask with elliptical openings. The openings are patterned to provide vias with minor axis of approximately 15 μm, so that twice the minor axis, which constitutes the vertical dimension of the vias 402, 403, is approximately 30 μm. Moreover, the major axis is selected to be approximately 25 μm to approximately 30 μm, so that twice the major axis, which constitutes the horizontal dimension of the vias 402, 403, is approximately 50 μm to approximately 60 μm. After etching through the wafer 401 is completed, the vias are metallized in a manner described above.

The dimensions and eccentricity of the vias are merely representative and not intended to be limiting. Rather, the selection of the major and minor axes is predicated upon a desired packing density, with considerations for the aspect ratio and resultant etch rate.

In view of this disclosure it is noted that the various method for fabricating vias and the resultant vias described herein can be implemented in a variety of materials and variant structures. Moreover, applications other than through-wafer vias may benefit from the present teachings. Further, the various materials, structures and parameters are included by way of example only and not in any limiting sense. In view of this disclosure, those skilled in the art can implement the present teachings in determining their own applications and needed materials and equipment to implement these applications, while remaining within the scope of the appended claims.

1. A semiconductor structure, comprising:
a substrate having a front surface and a back surface;
a via extending from the first surface, the via comprising:
a first side;
a second side parallel to the first side;
a first end extending between the first side and the second side;
a second end opposite to the first end and extending between the first side and the second side, wherein the first and second ends form oblique angles with the first and second sides.

2. A semiconductor structure as claimed in claim 1, wherein the first end is a semi-ellipse.

3. A semiconductor structure as claimed in claim 1, wherein the second end is a semi-ellipse.

4. A semiconductor structure as claimed in claim 1, wherein the first end and the second end are each semi-ellipses having the same eccentricity.

5. A semiconductor structure as claimed in claim 4, wherein the eccentricity is zero.

6. A semiconductor structure as claimed in claim 4, wherein the eccentricity is greater than zero but less than 1.

7. A semiconductor structure as claimed in claim 1, wherein the first side has a first length, the second side has a second length, and the first and second sides are separated by a distance that is less than either the first length or the second length.

8. A semiconductor structure as claimed in claim 7, wherein the ratio of the distance to a depth of the via is approximately 3:1.

9. A semiconductor structure as claimed in claim 1, wherein the substrate comprises a III-V semiconductor material.

10. A semiconductor structure as claimed in claim 1, wherein the substrate comprises silicon.

11. A method of forming a via in a substrate, the method comprising:
patterning a layer of photoresist over the substrate to form an opening in the photoresist, wherein the opening comprises:
a first side;
a second side parallel to the first side;
a first end extending between the first side and the second side;
a second end opposite to the first end and extending between the first side and the second side, wherein the first and second ends form oblique angles with the first and second sides; and
etching through the substrate to form the via.

12. A method as claimed in claim 11, wherein the etching comprises plasma etching.

13. A method as claimed in claim 12, wherein the plasma etching is a high density inductively coupled plasma etch.

14. A semiconductor structure, comprising:
a substrate having a front surface and a back surface;
an elliptical via extending from the front surface through to the back surface, wherein the elliptical via has an two foci that do not coincide.

15. A semiconductor structure as claimed in claim 14, further comprising a conductive layer disposed in the via.

16. A semiconductor structure as claimed in claim 14, wherein the ellipse comprises a semi-major axis and a semi-minor axis and the semi-major axis is greater than the semi-minor axis.

17. A method of forming a via in a substrate, the method comprising:
patterning a layer of photoresist over the substrate to form an elliptical opening in the photoresist; and
etching through the substrate to form the via.

18. A method as claimed in claim 17, wherein the etching comprises plasma etching.

19. A method as claimed in claim 17, wherein the plasma etching is a high density inductively coupled plasma etch.

20. A method as claimed in claim 17, wherein the elliptical opening comprises a semi-major axis and a semi-minor axis and the semi-major axis is greater than the semi-minor axis.
